(19) United States
(12) Patent Application Publication
(10) Pub. No.: US 2025/0261545 A1
(43) Pub. Date: Aug. 14, 2025

(54) DISPLAY DEVICE

(71) Applicant: LG Display Co., Ltd., Seoul (KR)

(72) Inventors: YongCheol Kim, Gimpo-si (KR); Sohee Lee, Paju-si (KR); Eunhyung Lee, Goyang-si (KR)

(73) Assignee: LG Display Co., Ltd., Seoul (KR)

(21) Appl. No.: 18/986,256

(22) Filed: Dec. 18, 2024

(30) Foreign Application Priority Data
Feb. 8, 2024 (KR) 10-2024-0019773

(51) Int. Cl. H10K 59/80; H10K 50/19; H10K 59/122

(52) U.S. Cl. CPC H10K 59/878; H10K 59/122; H10K 50/19

(57) ABSTRACT

A display device in one example includes a planarization layer disposed over a substrate, a first bank and a base layer disposed over the planarization layer, an anode disposed over the planarization layer and a side surface of the first bank, a reflective layer disposed to cover the base layer, a second bank covering a part of the anode and the first bank and disposed over the anode and the first bank, an organic layer disposed over the substrate on which the second bank is disposed, and a cathode disposed over the organic layer. The second bank is not formed over the reflection pattern to further improve the light extraction efficiency in accordance with the reduction in the non-emission area.

### CROSS-REFERENCE TO RELATED APPLICATIONS

This application claims priority to Korean Patent Application No. 10-2024-0019773, filed on Feb. 8, 2024, in the Korean Intellectual Property Office, the entire disclosure of which is hereby expressly incorporated by reference into the present application.

### BACKGROUND

### Field

The present disclosure relates to a display device, and more particularly, to a display device with an improved light extraction efficiency.

### Discussion of the Related Art

Currently, in a full-scale information era, a field of a display device which visually expresses electrical information signals has been rapidly developed and studies are continued to improve the performances of various display devices such as a thin-thickness, a light weight, and low power consumption.

Among various display devices, an electroluminescent display device is a self-emitting display device that does not need a separate light source, which is different from a liquid crystal display device. Therefore, the light emitting display device can be manufactured to have a light weight and a small thickness. Further, since the electroluminescent display device is driven at a low voltage, it is advantageous not only in terms of power consumption, but also in terms of color implementation, a response speed, a viewing angle, a contrast ratio (CR). Therefore, it is expected to be utilized in various fields.

In the meantime, light emitted from an emission layer of the electroluminescent display device passes through various components of the electroluminescent display device to be released to the outside of the electroluminescent display device. However, some of the light emitted from the emission layer can be trapped in the electroluminescent display device without being released to the outside of the electroluminescent display device, so that the light extraction efficiency of the electroluminescent display device can become an issue.

### SUMMARY OF THE DISCLOSURE

An object to be achieved by the present disclosure is to provide a display device with an improved light extraction efficiency.

Another object to be achieved by the present disclosure is to provide a display device which improves a light extraction efficiency by reducing a non-emission area.

Still another object to be achieved by the present disclosure is to provide a display device which suppresses short-circuit due to metal burr and improves the light extraction efficiency.

Objects of the present disclosure are not limited to the above-mentioned objects, and other objects, which are not mentioned above, can be clearly understood by those skilled in the art from the following descriptions.

In order to achieve the objects as described above, according to an aspect of the present disclosure, a display device includes a planarization layer disposed over a substrate, a first bank and a base layer disposed on the planarization layer, an anode disposed over the planarization layer and a side surface of the first bank, a reflective layer disposed so as to cover the base layer, a second bank covering a part of the anode and the first bank and disposed over the anode and the first bank, an organic layer disposed over the substrate on which the second bank is disposed and a cathode disposed on the organic layer.

Other detailed matters of the example embodiments are included in the detailed description and the drawings.

According to the present disclosure, the light extraction efficiency of the display device can be improved using a side mirror type anode.

According to aspects of the present disclosure, a reflection pattern is installed in a main emission area and an anode around the reflection pattern is shorted using a laser to induce reflective emission. At this time, a second bank is not formed over the reflection pattern to further improve the light extraction efficiency in accordance with the reduction in the non-emission area.

Further, according to the present disclosure, the reflection pattern is formed on a top surface of the planarization layer in which a part of a thickness is removed (etched) to suppress the short-circuit by the metal burr and improve the light extraction efficiency.

Therefore, low power can be implemented to reduce the power consumption and greenhouse gases generated by power use can be reduced to implement environment/social/governance (ESG).

The effects according to the present disclosure are not limited to the contents exemplified above, and more various effects are included in the present disclosure.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a view schematically illustrating a configuration of a display device according to a first embodiment of the present disclosure;

FIG. 2 is a plan view schematically illustrating a display panel of FIG. 1;

FIG. 3 is a perspective view illustrating a structure in which a touch panel is embedded in a display panel according to the first embodiment of the present disclosure;

FIG. 4 is a cross-sectional view taken along the line I-I′ of FIG. 2;

FIGS. 5A and 5B are a plan view and a perspective view illustrating a part of a sub pixel;

FIGS. 6A and 6B are views illustrating an emission image;

FIGS. 7A to 7F are views sequentially illustrating manufacturing processes of a display panel according to the first embodiment of the present disclosure of FIG. 4;

FIG. 8 is a view illustrating a part of a cross-section of a display panel according to a second embodiment of the present disclosure;

FIGS. 9A and 9B are a plan view and a perspective view illustrating a part of a sub pixel;

FIGS. 10A and 10B are a plan view and a perspective view illustrating a part of a sub pixel according to a third embodiment of the present disclosure;

FIG. 11 is a view illustrating an emission image;

FIG. 12 is a view illustrating a part of a cross-section of a display panel according to a fourth embodiment of the present disclosure; and

FIG. 13 is a plan view illustrating a part of a sub pixel according to an embodiment of the present disclosure.

### DETAILED DESCRIPTION OF THE EMBODIMENTS

Advantages and characteristics of the present disclosure and a method of achieving the advantages and characteristics will be clear by referring to embodiments described below in detail together with the accompanying drawings. However, the present disclosure is not limited to the embodiments disclosed herein but will be implemented in various forms. The embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the embodiments of the present disclosure are merely examples, and the present disclosure is not limited thereto. Like reference numerals generally denote like elements throughout the disclosure. Further, in the following description of the present disclosure, a detailed explanation of known related technologies can be omitted to avoid unnecessarily obscuring the subject matter of the present disclosure. The terms such as “including,” “having,” and “consist of” used herein are generally intended to allow other components to be added unless the terms are used with the term “only”. Any references to singular can include plural unless expressly stated otherwise.

Components are interpreted to include an ordinary error range even if not expressly stated.

When the position relation between two parts is described using the terms such as “on”, “over”, “above”, “below”, and “next”, one or more parts can be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components, and may not define order or sequence. Therefore, a first component to be mentioned below can be a second component in a technical concept of the present disclosure.

Like reference numerals generally denote like elements throughout the disclosure. Further, the term “can” fully encompasses all the meanings and coverages of the term “may.”

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, various embodiments of the present disclosure will be described in detail with reference to the drawings. All the components of each display device according to all embodiments of the present disclosure are operatively coupled and configured.

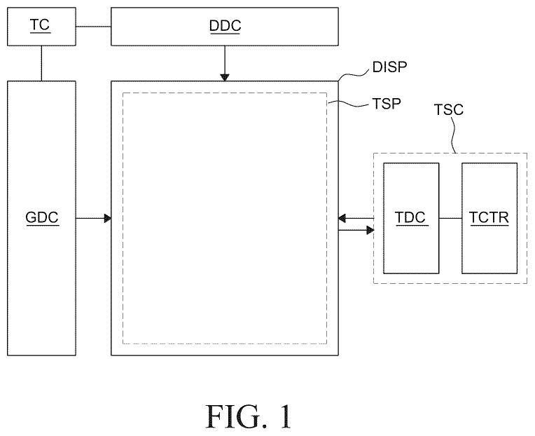

FIG. 1 is a view schematically illustrating a configuration of a display device according to a first embodiment of the present disclosure.

For example, FIG. 1 illustrates a schematic configuration of a display device in which a touch panel TSP according to a first embodiment of the present disclosure is embedded. However, the present disclosure is not limited thereto and a display device according to the embodiments of the present disclosure may not include a display panel.

Referring to FIG. 1, the display device according to the first embodiment of the present disclosure can provide both an image displaying function and a touch sensing function.

In order to provide an image displaying function, the display device according to the first embodiment of the present disclosure can include a display panel DISP, a gate driving circuit GDC, a data driving circuit DDC, and a timing controller TC.

For example, in the display panel DISP, a plurality of data lines and a plurality of gate lines are disposed and a plurality of sub pixels defined by the plurality of data lines and the plurality of gate lines can be disposed.

The data driving circuit DDC drives a plurality of data lines and the gate driving circuit GDC drives a plurality of gate lines, and the timing controller TC controls an operation of the data driving circuit DDC and the gate driving circuit GDC.

Each of the data driving circuit DDC, the gate driving circuit GDC, and the timing controller TC can be implemented by one or more individual components. In some cases, two or more of the data driving circuit DDC, the gate driving circuit GDC, and the timing controller TC can be implemented to be integrated as one component. For example, the data driving circuit DDC and the timing controller TC can be implemented as one integrated chip (IC chip).

In order to provide a touch sensing function, the display device according to the first embodiment of the present disclosure can include a touch panel TSP and a touch sensing circuit TSC. The touch panel TSP includes a plurality of touch electrodes. The touch sensing circuit TSC supplies a touch driving signal to the touch panel TSP and detects a touch sensing signal from the touch panel TSP to sense the presence of a touch of a user or a touch position (touch coordinate) in the touch panel TSP based on the detected touch sensing signal.

For example, the touch sensing circuit TSC can include a touch driving circuit TDC, a touch controller TCTR, and the like. The touch driving circuit TDC supplies a touch driving signal to the touch panel TSP and detects a touch sensing signal from the touch panel TSP. The touch controller TCTR senses the presence of a touch of a user and/or a touch position in the touch panel TSP based on the touch sensing signal detected by the touch driving circuit TDC. The touch driving circuit TDC can include a first circuit part which supplies the touch driving signal to the touch panel TSP and a second circuit part which detects the touch sensing signal from the touch panel TSP.

For example, the touch driving circuit TDC and the touch controller TCTR can be implemented by separate components or in some cases, can be implemented to be integrated as one component.

For example, each of the data driving circuit DDC, the gate driving circuit GDC, and the touch driving circuit TDC can be implemented by one or more integrated circuits. From the viewpoint of electrical connection with the display panel DISP, the circuits can be implemented by a chip on glass (COG) type, a chip on film (COF) type, or a tape carrier package (TCP) type. Further, the gate driving circuit GDC can also be implemented by a gate in panel (GIP) type.

For example, each of circuit configurations DDC, GDC, and TC for display driving and circuit configurations TDC and TCTR for touch sensing can be implemented by one or more individual components. In some cases, one or more of circuit configurations DDC, GDC, and TC for display driving and one or more of circuit configurations TDC and TCTR for touch sensing are functionally integrated to be implemented by one or more components.

For example, the data driving circuit DDC and the touch driving circuit TDC can be implemented to be integrated in one or two or more integrated circuit chips. When the data driving circuit DDC and the touch driving circuit TDC are implemented to be integrated in two or more integrated circuit chips, each of two or more integrated circuit chips can have a data driving function and a touch driving function.

In the meantime, the display device according to the first embodiment of the present disclosure can be various types, such as a light emitting display device or a liquid crystal display device. Hereinafter, for the convenience of description, a light emitting display device will be described as an example of the display device. For example, even though the display panel DISP can be various types such as a light emitting display panel or a liquid crystal display panel, in the following description, for the convenience of description, a light emitting display panel will be described as an example of the display panel DISP.

Further, as it will be described below, the touch panel TSP can include a plurality of touch electrodes which is applied with a touch driving signal or detects a touch sensing signal and a plurality of touch routing lines which connects the plurality of touch electrodes to the touch driving circuit TDC.

The touch panel TSP can be provided at the outside of the display panel DISP. For example, the touch panel TSP and the display panel DISP can be separately manufactured to be combined. Such a touch panel TSP is called an external type or an add-on type.

In contrast, the touch panel TSP can be embedded in the display panel DISP. For example, when the display panel DISP is manufactured, a touch sensor structure such as a plurality of touch electrodes and a plurality of touch routing lines which configure the touch panel TSP can be formed together with a plurality of electrodes and signal lines for display driving. Such a touch panel TSP is called an in-cell type.

Further, the touch panel TSP can be formed directly over an encapsulation unit of the display panel DISP. For example, the touch insulating film and the touch electrodes are patterned over the encapsulation unit and are connected to signal lines formed as electrodes for display driving to be driven. Such a touch panel TSP is called an on-cell type.

Hereinafter, for the convenience of description, an on-cell type in which the touch panel TSP is formed directly over the encapsulation unit will be described as an example.

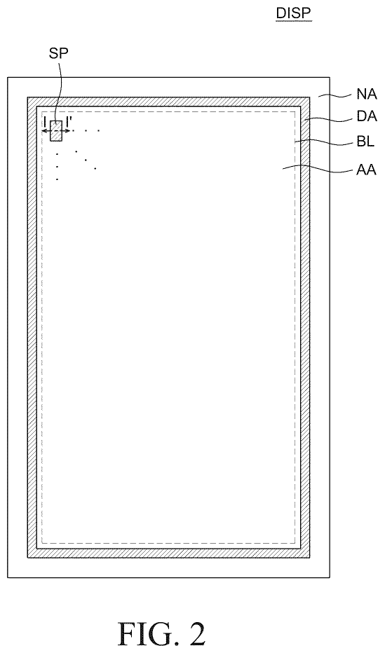

FIG. 2 is a plan view schematically illustrating a display panel of FIG. 1.

Referring to FIG. 2, the display panel DISP can include an active area AA (or display area) in which images are displayed and a non-active area NA (or non-display area) which is an outer area of an outer boundary line BL of the active area AA. The non-active area NA can surround the active area AA entirely or only in part(s).

In the active area AA of the display panel DISP, a plurality of sub pixels SP for displaying images is disposed and various electrodes or signal lines for display driving are disposed.

Further, in the active area AA of the display panel DISP, a plurality of touch electrodes for touch sensing and a plurality of touch routing lines electrically connected thereto can be disposed. Accordingly, the active area AA can also be referred to as a touch sensing area which is capable of sensing the touch.

In the non-active area NA of the display panel DISP, link lines extending from various signal lines disposed in the active area AA or link lines which are electrically connected to various signal lines disposed in the active area AA, and pads which are electrically connected to the link lines can be disposed. The pads disposed in the non-active area NA can be bonded or electrically connected with the display driving circuit.

Further, in the non-active area NA of the display panel DISP, link lines extending from a plurality of touch routing lines disposed in the active area AA or link lines which are electrically connected to a plurality of touch routing lines disposed in the active area AA, and pads which are electrically connected to the link lines can be disposed. The pads disposed in the non-active area NA can be bonded or electrically connected with the touch driving circuit.

In the non-active area NA, a part of an outermost touch electrode, among a plurality of touch electrodes disposed in the active area AA, extends or one or more electrodes (touch electrodes) formed of the same material as the plurality of touch electrodes disposed in the active area AA can be further disposed.

For example, all the plurality of touch electrodes disposed in the display panel DISP can be present in the active area AA or some (for example, an outermost touch electrode) among the plurality of touch electrodes disposed in the display panel DISP can be present in the non-active area NA. Some (for example, an outermost touch electrode) among the plurality of touch electrodes disposed in the display panel DISP can be present over the active area AA and the non-active area NA.

In the meantime, referring to FIG. 2, the display panel DISP according to the first embodiment of the present disclosure can include a dam area DA having a dam for suppressing any layer (for example, the encapsulation unit in the display panel) in the active area AA from passing over the outside of the display panel DISP.

The dam area DA can be located at a boundary of the active area AA and the non-active area NA or at any one position of a non-active area NA which is an outer area of the active area AA.

A dam disposed in the dam area DA can be disposed to enclose all directions of the active area AA or disposed only at an outside of one or two or more parts of the active area AA.

The dam disposed in the dam area DA can have one pattern which is connected or two or more separated patterns. Further, in the dam area DA, only a primary dam can be disposed or two or more dams (primary dam and secondary dam) can be disposed, or three or more dams can also be disposed.

For example, in the dam area DA, in any one direction, only the primary dam is disposed and in the other direction, both the primary dam and the secondary dam can be disposed.

In the meantime, the display panel DISP of the first embodiment of the present disclosure can include an always-on-display (AOD) driving area which always drives a part of the active area AA even in a turned-off state of the display device to transfer information. The AOD driving area can include a state bar area which displays a state of the display device.

For example, when the AOD is displayed on the active area AA, sub pixels SP in the AOD driving area are activated, but sub pixels in areas other than the AOD driving area are inactivated. Accordingly, when the AOD is displayed on the active area AA, only sub pixels in the AOD driving area can be driven.

Further, for example, the display panel (DISP) driving circuit can drive only sub pixels SP of the AOD driving area in the AOD driving mode under the control of the timing controller (TC in FIG. 1) to display data of predetermined AOD information in the sub pixels SP of the AOD driving area. Accordingly, in the AOD driving mode, only the sub pixels SP of the AOD driving area are activated and the sub pixels SP in an area other than the AOD driving area are not driven to be inactivated.

In the display device of the present disclosure, a side mirror (SM) structure is formed in a metal reflective plate having a height and a gradient in the vicinity of the emission area, for example, in the anode to apply an optical side mirror (OSM) technique which extracts light which is laterally lost, to the front surface. Light emitted from the light emitting diode in the sub pixel is reflected from the SM structure of the inclined anode to be extracted to the outside. The smaller the sub pixel, for example, the higher the pixels per inch (PPI), the shorter the distance from the taper so that the efficiency according to the application of the OSM technique can be further increased.

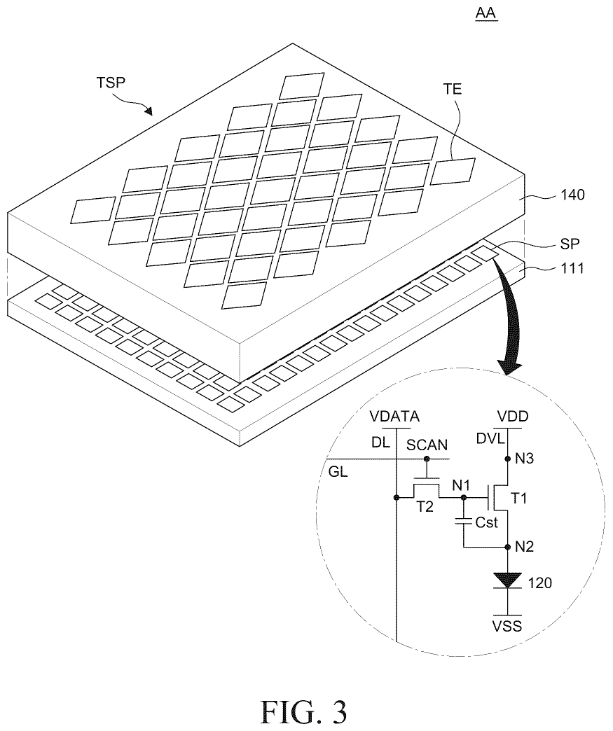

FIG. 3 is a perspective view illustrating a structure in which a touch panel is embedded in a display panel. Particularly, FIG. 3 is a perspective view illustrating a structure in which a touch panel is embedded in a display panel according to the first embodiment of the present disclosure.

Referring to FIG. 3, for example, in the active area AA of the display panel (DISP in FIG. 2), a plurality of sub pixels SP can be disposed over the substrate 111.

Each sub pixel SP can include a light emitting diode 120, a first transistor T1 for driving the light emitting diode 120, a second transistor T2 for transmitting a data voltage VDATA to a first node N1 of the first transistor T1, and a storage capacitor Cst for maintaining a constant voltage for one frame.

For example, the first transistor T1 can include a first node N1 to which the data voltage VDATA is applied, a second node N2 which is electrically connected to the light emitting diode 120, and a third node N3 to which a driving voltage VDD is applied from a driving voltage line DVL. The first node N1 can be a gate node, the second node N2 can be a source node or a drain node, and the third node N3 can be a drain node or a source node. The first transistor T1 can also be referred to as a driving transistor which drives the light emitting diode 120.

The light emitting diode 120 can include a first electrode (for example, an anode), an emission layer, and a second electrode (for example, a cathode). The first electrode is electrically connected to the second node N2 of the first transistor T1 and the second electrode can be applied with a base voltage VSS.

The emission layer in the light emitting diode 120 can be configured by an organic material or an inorganic material.

For example, the second transistor T2 is controlled to be turned on or off by a scan signal SCAN applied through the gate line GL and can be electrically connected between the first node N1 of the first transistor T1 and the data line DL. Further, the second transistor T2 can be referred to as a switching transistor.

For example, when the second transistor T2 is turned on by the scan signal SCAN, the second transistor T2 can transmit the data voltage VDATA supplied from the data line DL to the first node N1 of the first transistor T1.

The storage capacitor Cst can be electrically connected between the first node N1 and the second node N2 of the first transistor T1.

Each sub pixel SP can have a 2T1C structure including two transistors T1 and T2 and one capacitor Cst and in some cases, can further include one or more transistors or further include one or more capacitors.

The storage capacitor Cst is not a parasitic capacitor (for example, Cgs or Cgd) which is an internal capacitor present between the first node N1 and the second node N2 of the first transistor T1, but can be an external capacitor which is intentionally designed at the outside of the first transistor T1.

The first transistor T1 and the second transistor T2 can be configured by an n-type transistor or a p-type transistor. As described above, in the display panel DISP, circuit elements such as a light emitting diode 120, two or more transistors T1 and T2, and one or more capacitors Cst can be disposed. The circuit element (specifically, the light emitting diode 120) is vulnerable to external moisture or oxygen so that an encapsulation unit 140 for suppressing the external moisture or oxygen from permeating the circuit element can be disposed on the display panel DISP.

The encapsulation unit 140 can be formed by one layer, or also formed by a plurality of layers.

In the meantime, in the display device according to the first embodiment of the present disclosure, the touch panel TSP can be disposed over the encapsulation unit 140. For example, in the display device according to the first embodiment of the present disclosure, a touch sensor structure, such as a plurality of touch electrodes TE which configures a touch panel TSP, can be disposed over the encapsulation unit 140.

During the touch sensing, a touch driving signal or a touch sensing signal can be applied to the touch electrode TE. Accordingly, during the touch sensing, a potential difference is formed between the touch electrode TE and the cathode which are disposed with the encapsulation unit 140 therebetween so that an unnecessary parasitic capacitance can be formed. At this time, the parasitic capacitance can degrade a touch sensitivity. Therefore, in order to lower the parasitic capacitance, a distance between the touch electrode TE and the cathode can be designed to be equal to or larger than a predetermined value (for example, 1 μm) in consideration of a thickness of the display panel DISP, a display panel (DISP) manufacturing process, and a display performance. To this end, for example, the thickness of the encapsulation unit 140 can be designed to be at least 1 μm or larger.

In the meantime, the display device according to the first embodiment of the present disclosure can sense the touch based on capacitance formed in the touch electrode TE.

The display device according to the first embodiment of the present disclosure employs a capacitance-based touch sensing manner so that the touch can be sensed by a mutual-capacitance-based touch sensing manner or a self-capacitance-based touch sensing manner.

For example, according to the mutual-capacitance-based touch sensing manner, a plurality of touch electrodes TE can be classified into a driving touch electrode (a transmission touch electrode) to which a touch driving signal is applied and a sensing touch electrode (a reception touch electrode) which detects a touch sensing signal and forms a capacitance with the driving touch electrode.

In the case of the mutual-capacitance-based touch sensing manner, the touch sensing circuit can sense the presence of the touch and/or the touch coordinate based on the change in capacitance (mutual-capacitance) between the driving touch electrode and the sensing touch electrode depending on the presence of a pointer such as a finger or a pen.

According to the self-capacitance-based touch sensing manner, each touch electrode TE can serve as both a driving touch electrode and a sensing touch electrode. For example, the touch sensing circuit applies a touch driving signal to one or more touch electrodes TE and detects a touch sensing signal by means of the touch electrode TE applied with the touch driving signal. The touch sensing circuit identifies the change in capacitance between a pointer such as a finger or a pen and the touch electrode TE based on the detected touch sensing signal to sense the presence of touch and/or the touch coordinate. In the self-capacitance-based touch sensing manner, the driving touch electrode and the sensing touch electrode are not distinguished.

As described above, the display device according to the first embodiment of the present disclosure can sense the touch in the mutual-capacitance-based touch sensing manner or the self-capacitance-based touch sensing manner. However, in the following description, for the convenience of description, it will be described that the display device performs mutual-capacitance-based touch sensing and includes a touch sensor structure therefor, as an example.

Hereinafter, a configuration of a sub pixel according to an embodiment of the present disclosure will be described in detail with reference to the drawings.

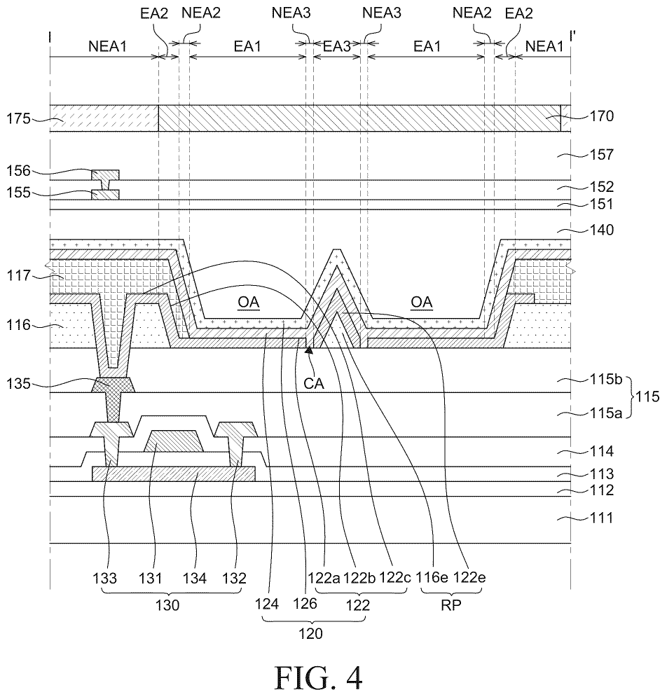

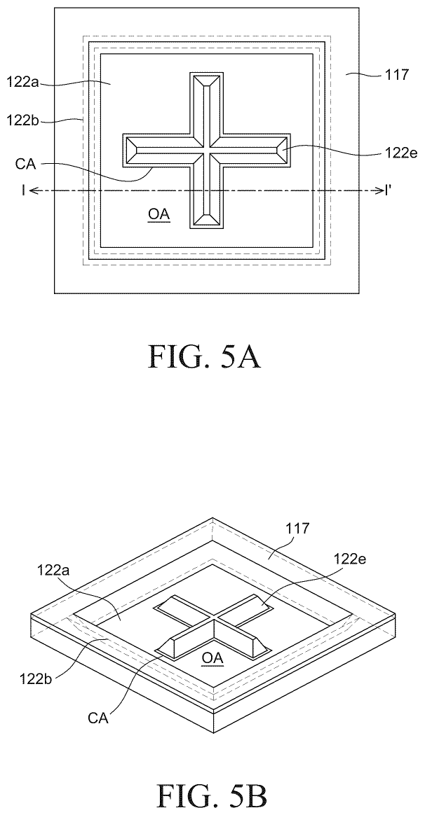

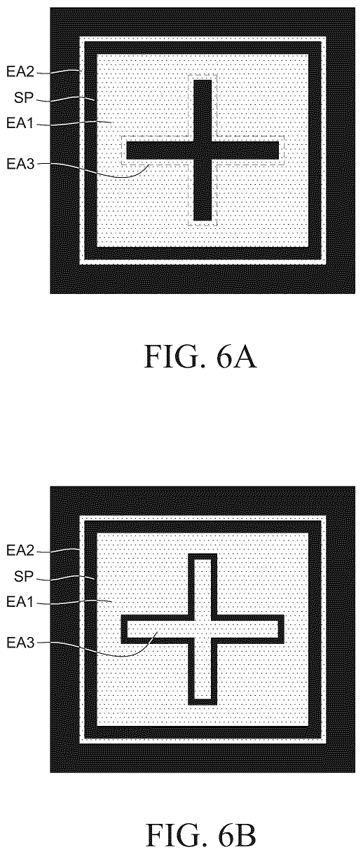

FIG. 4 is a cross-sectional view taken along the line I-I′ of FIG. 2. FIGS. 5A and 5B are respectively a plan view and a perspective view illustrating a part of a sub pixel. FIGS. 6A and 6B are views illustrating an emission image.

More specifically, FIG. 4 illustrates a part of a cross-sectional structure of one sub pixel SP taken along the line I-I′ of FIG. 2 or 5A.

FIG. 5A is a plan view illustrating an example that a second bank 117 is disposed over the anode 122 of FIG. 4 and FIG. 5B is a perspective view of FIG. 5A. Here, in FIGS. 5A and 5B, for the convenience of description, configurations over the anode 122 and the second bank 117 are omitted.

FIG. 6A illustrates an emission image of a comparative embodiment in which a second bank is formed over a reflection pattern and a cutting area is not formed around the reflection pattern. FIG. 6B illustrates an emission image of the first embodiment in which a second bank 117 is not formed over a reflection pattern RP and the cutting area CA is formed around the reflection pattern RP.

Referring to FIGS. 4, 5A, and 5B, the display panel of the first embodiment of the present disclosure can include a plurality of pixels configured by a first sub pixel, a second sub pixel, and a third sub pixel.

The first sub pixel, the second sub pixel, and the third sub pixel have different shapes, but have substantially the same configuration. However, these are not limited thereto and the first sub pixel, the second sub pixel, and the third sub pixel can have the same shape.

For example, the first sub pixel can be a red sub pixel. The second sub pixel can be a green sub pixel. The third sub pixel can be a blue sub pixel. However, the present disclosure is not limited thereto and can further include a fourth sub pixel which is a white sub pixel.

For example, the sub pixel SP can have an approximately rectangular shape, but is not limited thereto. At this time, a shape of the sub pixel SP can be defined by a shape of a first area 122a of the anode 122, but it is not limited thereto.

In the meantime, in the first embodiment of the present disclosure, the anode 122 has a side mirror (SM) structure so that a first reflective emission area EA2 is added in addition to the main emission area EA1 so that each emission area can expand to be larger than each sub pixel SP.

Further, in the first embodiment of the present disclosure, a reflection pattern RP is installed in the main emission area EA1 and a cut (ruptured) area CA in which the first area 122a of the anode 122 is cut is formed around the reflection pattern RP by means of the laser to add the second reflective emission area EA3. Specifically, a second bank 117 is not formed over the reflection pattern RP to further improve the light extraction efficiency in accordance with the reduction in the non-emission area.

A buffer layer 112, such as a multi-buffer layer or a lower buffer layer, can be disposed over the substrate 111.

The flexible substrate 111 can use a ductile material having a flexible characteristic, such as plastic.

The substrate 111 can be a film type including one of a group consisting of a polyester-based polymer, a silicon-based polymer, an acrylic polymer, a polyolefin-based polymer, and a copolymer thereof.

The substrate 111 can include a first substrate, a second substrate, and an insulating film. The insulating film can be disposed between the first substrate and the second substrate. As described above, the substrate 111 is configured by the first substrate, the second substrate, and the insulating film to suppress the moisture permeation. For example, the first substrate and the second substrate can be polyimide (PI) substrates.

For example, the multi-buffer layer can delay the spreading of the moisture or oxygen permeating the substrate 111 and can be formed by alternately laminating silicon nitride (SiNx) and silicon oxide (SiOx) at least once.

For example, the lower buffer layer can perform a function of protecting the semiconductor layer 134 and blocking various types of defects entering from the substrate 111.

For example, the lower buffer layer can be formed by amorphous silicon, silicon nitride (SiNx), or silicon oxide (SiOx).

The switching thin film transistor (T2 in the pixel driving circuit of FIG. 3) and the driving thin film transistor 130 (T1 in the pixel driving circuit of FIG. 3) can be disposed over the buffer layer 112.

The semiconductor layer 134 can be disposed in the active area on the buffer layer 112.

For example, the semiconductor layer 134 can be formed of a polycrystalline semiconductor and include a channel region, a source region, and a drain region. However, it is not limited thereto and the semiconductor layer 134 can be configured by amorphous silicon or oxide semiconductor.

The gate insulating film 113 can be disposed on the semiconductor layer 134.

The gate insulating film 113 can be configured by a single layer of silicon nitride (SiNx) or silicon oxide (SiOx) or a multilayer thereof.

A gate line is disposed in a first direction and a gate electrode 131 which is connected to the gate line can be disposed, on the gate insulating film 113.

The gate electrode 131 can be disposed on the gate insulating film 113 so as to overlap the semiconductor layer 134.

For example, the gate electrode 131 and the gate line can be configured by a single layer or multiple layers of copper (Cu), aluminum (Al), molybdenum (Mo), chrome (Cr), gold (Au), titanium (Ti), nickel (Ni), and neodymium (Nd) which are conductive metals or an alloy thereof, but are not limited thereto.

An interlayer insulating film 114 can be disposed on the gate electrode 131 so as to cover the gate electrode 131.

For example, the interlayer insulating film 114 can be configured by a single layer of silicon nitride (SiNx) or silicon oxide (SiOx) or a multilayer thereof.

At this time, a partial area of the interlayer insulating film 114 and the gate insulating film 133 is selectively removed to form a plurality of contact holes which exposes both ends of the semiconductor layer 134.

The data line can be disposed on the interlayer insulating film 114 in a second direction intersecting the gate line.

Further, a source electrode 132 and a drain electrode 133 which are connected to both ends of the semiconductor layer 134 are disposed on the interlayer insulating film 114.

A protective film can be disposed on the data line and the source electrode 132 and the drain electrode 133. The protective film can be omitted as needed.

The protective film can be formed as a single layer of silicon nitride (SiNx) or silicon oxide (SiOx) or a multilayer thereof.

A planarization layer 115 can be disposed on the protective film. The planarization layer 115 can have a multi-layered structure configured by at least two layers and for example, can include a first planarization layer 115a and a second planarization layer 115b. The first planarization layer 115a is disposed to cover the driving thin film transistor 130 and expose a part of the drain electrode 133 of the driving thin film transistor 130.

A thickness of the planarization layer 115 is approximately 2 μm, but is not limited thereto.

The planarization layer 115 can be an overcoat layer, but is not limited thereto.

For example, the connection electrode 135 can be disposed on the first planarization layer 115a to electrically connect the driving thin film transistor 130 and the light emitting diode 120. Further, various metal layers which serve as wiring lines/electrodes, such as a signal line, other than the data line, can be disposed on the first planarization layer 115a.

The connection electrode 135 can be configured with a material, such as copper (Cu), aluminum (Al), molybdenum (Mo), chrome (Cr), gold (Au), titanium (Ti), nickel (Ni), and neodymium (Nd), or an alloy thereof.

Further, the second planarization layer 115b can be disposed on the first planarization layer 115a and the connection electrode 135.

For example, since various signal lines are increased in accordance with the increased resolution of the display panel, the planarization layer 115 is formed by two layers in the display panel according to the first embodiment of the present disclosure. Therefore, it can be difficult to dispose all the wiring lines on one layer while ensuring a minimum interval so that an additional layer is provided. Such an additional layer, for example, the second planarization layer 115b is added so that there is a margin for disposing wiring lines, which makes it easier to design and dispose the wiring lines/electrodes. Further, when a dielectric material is used for the planarization layer 115 configured by a plurality of layers, the planarization layer 115 can be utilized to form a capacitance between metal layers.

The second planarization layer 115b can be formed to expose a part of the connection electrode 135 and the drain electrode 133 of the driving thin film transistor 130 and the anode 122 of the light emitting diode 120 can be electrically connected by the connection electrode 135.

The planarization layer 115 can be configured by one or more materials of acrylic resin, epoxy resin, phenolic resin, polyamides resin, polyimides resin, unsaturated polyesters resin, polyphenylene resin, benzocyclobutene, and polyphenylenesulfides resin, but is not limited thereto.

The first bank 116 can be disposed on the second planarization layer 115b.

For example, the first bank 116 can be disposed in a first non-emission area NEA1 and a first reflective emission area EA2 of the substrate 111 on the second planarization layer 115b. The first non-emission area NEA1 and the first reflective emission area EA2 can be disposed around the main emission area EA1.

The first non-emission area NEA1 can be located so as to correspond to the first bank 116 in which the second area 122b of the anode 122 is not located. Further, a second non-emission area NEA2 can be located between the main emission area EA1 and the first reflective emission area EA2. The second non-emission area NEA2, the first reflective emission area EA2, and the first non-emission area NEA1 can be sequentially disposed around the main emission area EA1.

The first bank 116 can be formed of an organic material. For example, the first bank 116 can be formed of polyimide, acrylic, or benzocyclobutene resin, but is not limited thereto.

Further, the first bank 116 can be formed of a black material. For example, the first bank 116 can be configured such that the black pigment is dispersed in an organic material, but is not limited thereto and as long as the first bank has a black color, the first bank can be configured by an arbitrary material. Further, for example, the organic material can be cardo-based polymer and polymer including epoxy acrylate, but is not limited thereto. As the first bank 116 includes the black material, the first bank 116 can reduce external light reflection, specifically, scattered reflection which can be generated by a transparent second bank 117. For example, in order to reduce the reflection of external light, an optical density of the first bank 116 can be configured to be 4 or lower at the thickness of 3 μm of the first bank 116, but is not limited thereto. Further, in order to reduce the reflection of the external light, the reflectance of the first bank 116 can be 1% or lower, but is not limited thereto.

In the meantime, according to the first embodiment of the present disclosure, a reflection pattern RP with an inclined side surface is disposed over the second planarization layer 115b in which the first bank 116 is not disposed. For example, the reflection pattern RP can be located in the main emission area EA1.

The reflection pattern RP has an inclined side surface and a triangular cross-section overall, but is not limited thereto.

Further, for example, in the plan view, the reflection pattern RP can have a cross-shape which divides the main emission area EA1 into four, but the present disclosure is not limited thereto and can have a lattice shape which divides the main emission area EA1 into four or more.

When it is assumed that if a division number is 1, the main emission area EA1 is divided into four and if a division number is 2, the main emission area EA1 is divided into nine, if a taper height of the reflection pattern RP is 2 μm, the efficiency can be improved by approximately 100% to 150% with the division number of 2 to 6. Further, if a taper height of the reflection pattern RP is 1.5 the efficiency can be improved by approximately 140% to 180% with the division number of 2 to 6.

Further, the reflection pattern RP can be spaced apart from the first area 122a of the anode 122 by a predetermined distance. The reflection pattern RP of the present disclosure is not in contact with the first area 122a of the anode 122.

For example, the reflection pattern RP can be configured by a base layer 116e formed of an organic material and a reflective layer 122e formed of a reflective material, but is not limited thereto.

For example, the base layer 116e can be configured by the same organic material as the first bank 116, but is not limited thereto. The base layer 116e can be configured by the same process as the first bank 116, but is not limited thereto. Further, the base layer 116e has an inclined side surface and a triangular cross-section, but is not limited thereto.

Further, for example, in the plan view, the base layer 116e can have a cross-shape which divides the main emission area EA1 into four, but the present disclosure is not limited thereto and can have a lattice shape which divides the main emission area EA1 into four or more. Here, an overall shape of the reflection pattern RP can be determined in accordance with the shape of the base layer 116e.

For example, the reflective layer 122e can be configured by the same conductive material as the anode 122, but is not limited thereto. The reflective layer 122e can be formed by the same photo process as the anode 122, but is not limited thereto. Further, the reflective layer 122e can be formed to cover a side surface of the base layer 116e. Further, the reflective layer 122e can be formed to cover the entire base layer 116e. The reflective layer 122e includes a reflective film of the anode 122 to reflect upwardly light which travels to the side surface of the reflection pattern RP to form a second reflective emission area EA3 between the main emission areas EA1. At this time, a third non-emission area NEA3 can be located between the main emission area EA1 and the second reflective emission area EA3.

Further, for example, in the plan view, the reflective layer 122e can have a cross-shape which divides the main emission area EA1 into four, but the present disclosure is not limited thereto and can have a lattice shape which divides the main emission area EA1 into four or more.

In the meantime, according to the first embodiment of the present disclosure, a cut (ruptured) area CA in which the first area 122a of the anode 122 is cut (or removed) is provided around the reflection pattern RP. At this time, a third non-emission area NEA3 can be located between the main emission area EA1 and the second reflective emission area EA3 by the cutting area CA.

The cutting area CA is formed by cutting (or removing) the first area 122a of the anode 122 around the reflection pattern RP to expose the second planarization layer 115b therebelow. Accordingly, the reflective layer 122e of the reflection pattern RP can be separated from the first area 122a of the anode 122. For example, the reflection pattern RP can be electrically isolated.

For example, in the plan view, the cutting area CA can have a cross-shape which divides the main emission area EA1 into four in accordance with the shape of the reflection pattern RP, but the present disclosure is not limited thereto and can have a lattice shape which divides the main emission area EA1 into four or more.

The cutting area CA can be formed using the laser.

In the meantime, as described above, according to the present disclosure, the second bank 117 is not formed over the reflection pattern RP. In this case, the non-emission area in the sub pixel SP is reduced to further improve the light extraction efficiency.

For example, referring to FIGS. 6A and 6B, when the side mirror shape anode is used, the first reflective emission area EA2 is added around the main emission area EA1 by the side mirror (SM) structure of the anode so that each emission area can expand to be larger than each sub pixel SP. Further, when the reflection pattern is installed in the main emission area EA1, the second reflective emission area EA3 by the reflection pattern can be added.

However, when the reflection pattern is additionally formed in the sub pixel SP, the second bank needs to be formed over the reflection pattern to form the side mirror (SM) structure. In this case, referring to FIG. 6A, the emission area can be reduced as much as the width of the second bank in the sub pixel SP. For example, the reduction in the emission area results in the degradation of the efficiency. In this case, the overall efficiency can be reduced because the reduction in the efficiency by the reduction in the emission area is greater than the increase of the efficiency added by the reflection pattern.

In the meantime, when the second bank is not formed over the reflection pattern, the organic layer can be deposited to be thinner by the taper of the reflection pattern and in this case, a dark spot defect can be generated due to the short-circuit between the anode and the cathode.

In contrast, when the cutting area is formed around the reflection pattern as in the first embodiment of the present disclosure, the reflection pattern can be electrically isolated by the cutting area so that there is no need to form the second bank over the reflection pattern. In this case, the emission area can be maximized by removing the second bank (see FIG. 6B). For example, the increase of the efficiency added by the reflection pattern is greater than the reduction in the efficiency by the reduction in the emission area so that the overall efficiency can be increased.

In the meantime, the light emitting diode 120 which is electrically connected to the connection electrode 135 through a contact hole can be disposed over the second planarization layer 115b.

At this time, for example, the light emitting diode 120 can include an anode 122 connected to the drain electrode 133 of the driving thin film transistor 130, a plurality of organic layers 124 disposed on the anode 122, and a cathode 126 disposed on the organic layers 124. The organic layer 124 can be referred to as a light emitting unit, but is not limited to the term.

Further, for example, the anode 122 can include a first area 122a which is disposed on the second planarization layer 115b to be in contact with the second planarization layer 115b and a second area 122b which extends from the first area 122a to be disposed on the side surface of the first bank 116. The first area 112a has a surface substantially parallel to a surface of the substrate 111 and the second area 112b has a surface which has a predetermined angle with respect to the substrate 111. The surface of the second area 122b may not be parallel to the surface of the substrate 111.

Further, for example, the anode 122 can include a third area 122c which extends from the second area 122b in one direction to be electrically connected to the connection electrode 135 through a contact hole. Further, a reflective layer 122e of the reflection pattern RP which is separated from the first area 122a of the anode 122 by the cutting area CA can be disposed in the sub pixel SP. For example, the reflective layer 122e can correspond to the second reflective emission area EA3.

The anode 122 can be electrically connected to the source electrode 132 or the drain electrode 133 of the driving thin film transistor 130.

The anode 122 and the reflective layer 122e can include reflective films formed of a reflective metal.

In FIG. 4, for the convenience of description, an example that the anode 122 and the reflective layer 122e are configured as a single layer is illustrated, but the present disclosure is not limited thereto and the anode 122 and the reflective layer 122e can be configured as a multi-layered structure. When the anode 122 and the reflective layer 122e are configured as a multi-layered structure, at least one layer can include a reflective metal.

For example, the anode 122 and the reflective layer 122e can have a multi-layered structure including a transparent film configured by a transparent conductive film and a reflective film configured by an opaque conductive film having a high reflection efficiency. For example, the transparent conductive film can be configured with a material having a high work function, such as indium-tin-oxide (ITO) or indium-zinc-oxide (IZO) and the opaque conductive film can be configured with a single or multi-layered structure including copper (Cu), silver (Ag), aluminum (Al), molybdenum (Mo), titanium (Ti), or an alloy thereof. Further, for example, the anode 122 and the reflective layer 122e can be configured by a structure in which a transparent conductive film, an opaque conductive film, and a transparent conductive film are sequentially laminated or can be configured by a structure in which a transparent conductive film and an opaque conductive film are sequentially laminated.

In the meantime, the second area 122b of the anode 122 of the present disclosure can be disposed on the side surface of the first bank 116 in accordance with a shape of the side surface of the first bank 116. The second area 122b of the anode 122 disposed on the side surface of the first bank 116 can have a taper at an angle of approximately 30° to 60°, but is not limited thereto. Further, the reflective layer 122e of the present disclosure can be disposed so as to cover the base layer 116e in accordance with a shape of the base layer 116e. Further, the reflective layer 122e disposed on the side surface of the base layer 116e can have a taper at an angle of approximately 30° to 60°, but is not limited thereto. At this time, the second area 122b of the anode 122 and the reflective layer 122e including the reflective films can serve as a side mirror SM. Accordingly, the emission area according to the first embodiment of the present disclosure can further include a first reflective emission area EA2 and a second reflective emission area EA3 by the SM structure, in addition to the main emission area EA1. The first reflective emission area EA2 can be formed between the main emission area EA1 and the first non-emission area NEA1 so as to correspond to the second area 122b of the anode 122. The second reflective emission area EA3 can be formed between the main emission areas EA1 so as to correspond to the reflective layer 122e of the reflection pattern RP.

For example, in the plan view, the main emission area EA1 has a rectangular shape, the first reflective emission area EA2 has a rectangular frame shape, and the second reflective emission area EA3 has a cross-shape, but the present disclosure is not limited thereto. Further, for example, the main emission area EA1 can have a circular shape, an oval shape, or a polygonal shape and the first reflective emission area EA2 can have a circular shape, an oval shape, or a polygonal frame shape. Further, the second reflective emission area EA3 can have a circular shape, an oval shape, a polygonal shape, or a lattice shape.

When the display device according to the first embodiment of the present disclosure is a top emission type light emitting display device, the reflective films of the anode 122 and the reflective layer 122e can upwardly reflect the light emitted from the light emitting diode 120. For example, the light generated in the organic layer 124 of the light emitting diode 120 can be emitted not only upwardly, but also laterally. The laterally emitted light is directed into the display device, is trapped in the display device by the total reflection, or travels into the display device and then dissipates. Therefore, according to the present disclosure, the second area 122b of the anode 122 and the reflective layer 122e of the reflection pattern RP which include the reflective films are disposed on the side surfaces of the first bank 116 and the base layer 116e, respectively, to change a traveling direction of light which laterally travels to an upward direction. Therefore, the light extraction efficiency of the display device can be improved.

For example, the second bank 117 can be disposed over the first bank 116 and the anode 122 while covering a part of the anode 122.

For example, the second bank 117 can cover a part of the first area 122a and the second area 122b and the third area 122c of the anode 122. The second bank 117 can cover a part of an edge of the first area 122a. Further, the second bank 117 can cover the entire second area 122b and the entire third area 122c.

A part of the second bank 117 corresponding to the main emission area EA1 can be open. For example, the second bank 117 can include an open area OA obtained by removing (opening) a part corresponding to the main emission area EA1 of a sub pixel SP.

A part of the second bank 117 which corresponds to the second reflective emission area EA3 and the third non-emission area NEA3 can be additionally open. The reflection pattern RP can be located in the second reflective emission area EA3 and the third non-emission area NEA3 which are additionally open.

As described above, the sub pixel SP according to the first embodiment of the present disclosure can have a plurality of emission areas EA1, EA2, and EA3 and a plurality of non-emission areas NEA1, NEA2, and NEA3.

In each sub pixel SP, the main emission area EA1 can have a width larger than those of the first reflective emission area EA2 and the second reflective emission area EA3. In each sub pixel SP, the first non-emission area NEA1 can have a width larger than those of the second non-emission area NEA2 and the third non-emission area NEA3, but it is not limited thereto.

For example, the second non-emission area NEA2 can be located between the main emission area EA1 and the first reflective emission area EA2. The third non-emission area NEA3 can be located between the main emission area EA1 and the second reflective emission area EA3.

In each sub pixel SP, the first reflective emission area EA2 can be disposed around the main emission area EA1 and the second reflective emission area EA3 can be disposed in the main emission area EA1 of each sub pixel SP.

The second bank 117 can be formed of an organic material. For example, the second bank 117 can be formed of polyimide, acrylic, or benzocyclobutene resin, but is not limited thereto.

Further, the second bank 117 can be formed of a transparent material, but is not limited thereto.

The organic layer 124 can also be disposed on the top surface and a side portion of the second bank 117, including the open area OA of the second bank 117. Further, the organic layer 124 can be disposed and extend over the top surface and the side portion of the reflection pattern RP, including the cutting area CA.

For example, the organic layer 124 can include a hole injection layer, a hole transport layer, an emission layer, an electron transport layer, and an electron injection layer. In a tandem structure in which a plurality of emission layers is overlaid, a charge generation layer can be further disposed between the emission layers. The emission layer can emit different color light in every sub pixel. For example, each of a red emission layer, a green emission layer, and a blue emission layer can be separately disposed in every sub pixel, but the present disclosure is not limited thereto. However, a common emission layer is formed in every sub pixel to emit white light regardless of the color and a color filter which distinguishes the color can be separately provided. In this case, the emission layer can be individually disposed, but the hole injection layer, the electron injection layer, the hole transport layer, or the electron transport layer is provided as a common layer to be disposed in each sub pixel in the same way.

Further, the cathode 126 can be disposed on the organic layer 124 so as to be opposite to the anode 122 with the organic layer 124 therebetween. For example, when the cathode 126 is applied to a top emission type display device, the cathode can be configured by a transparent conductive film obtained by forming indium tin oxide (ITO), indium zinc oxide (IZO), or magnesium-silver (Mg—AG) to be thin.

The encapsulation unit 140 can be disposed over the cathode 126 to protect the light emitting diode 120.

The light emitting diode 120 can react to external moisture and oxygen due to a characteristic of the organic material of the organic layer 124 to cause dark-spot or pixel shrinkage. In order to suppress this problem, the encapsulation unit 140 can be disposed over the cathode 126. The encapsulation unit 140 can be configured by a first inorganic insulating film, a foreign material compensation layer, and a second inorganic insulating film, but is not limited thereto.

For example, the first inorganic insulating film can be disposed over the substrate 111 on which the cathode 126 is disposed to be the most adjacent to the light emitting diode 120.

For example, the first inorganic insulating film can be configured by an inorganic insulating material on which low-temperature deposition is allowed, such as silicon nitride (SiNx), silicon oxide (SiOx), silicon oxynitride (SiON), or aluminum oxide (Al₂O₃). The first inorganic insulating film is deposited under a low temperature atmosphere so that the damage of the organic layer 124 including an organic material vulnerable to the high temperature atmosphere during the deposition can be suppressed.

A foreign material compensation layer can be disposed to have a smaller area than the first inorganic insulating film and can be configured to expose both ends of the first inorganic insulating film. The foreign material compensation layer can be formed of an organic insulating material, such as acrylic resin, epoxy resin, polyimide, polyethylene, or silicon oxycarbon (SiOC).

In the meantime, when the foreign material compensation layer is formed by an inkjet method, one or more dams can be disposed in a boundary area of the non-active area and the active area or a dam area corresponding to a partial area in the non-active area. In such a dam area, a primary dam adjacent to the active area and a secondary dam adjacent to the pad unit can be disposed.

When a liquid type foreign material compensation layer is dropped in the active area, one or more dams disposed in the dam area can suppress the liquid type foreign material compensation layer from collapsing in the direction of the non-active area to invade the pad unit.

The primary dam and/or secondary dam can be configured as a single layer or a multiple-layered structure. For example, the primary dam and/or secondary dam can be simultaneously configured with the same material as at least one of the planarization layer 115, the first bank 116, the second bank 117, and the spacer. In this case, the dam structure can be configured without having the mask adding process and increasing the cost.

Further, the foreign material compensation layer including an organic material can be located only on an inner surface of the primary dam.

Further, the second inorganic insulating film can be disposed so as to cover an upper surface and a side surface of each of the first inorganic insulating film and the foreign material compensation layer. The second inorganic insulating film can serve to minimize or block the permeation of the external moisture or oxygen into the first inorganic insulating film and the foreign material compensation layer. The second inorganic insulating film can be formed of an inorganic insulating material, such as silicon nitride (SiNx), silicon oxide (SiOx), silicon oxynitride (SiON), and aluminum oxide (Al₂O₃).

A touch buffer film 151 can be disposed on the encapsulation unit 140.

A bridge pattern 155 can be disposed on the touch buffer film 151. However, it is not limited thereto and a touch electrode (or a touch line) can be disposed on the touch buffer film 151.

The touch buffer film 151 can be located between the bridge pattern 155 and the encapsulation unit 140.

For example, the touch buffer film 151 can be designed to maintain a predetermined minimum interval between the bridge pattern 155 and the cathode 126. By doing this, a parasitic capacitance which can be formed between the bridge pattern 155 and the cathode 126 can be reduced or suppressed so that degradation of the touch sensitivity due to the parasitic capacitance can also be suppressed.

The bridge pattern 155 can be disposed over the encapsulation unit 140 without having the touch buffer film 151.

The bridge pattern 155 can have a single layer or multi-layered structure formed of a metal having strong corrosion resistance and acid resistance, such as aluminum (Al), titanium (Ti), copper (Cu), or molybdenum (Mo).

The touch insulating film 152 can be disposed on the bridge pattern 155.

For example, the touch insulating film 152 can use an organic film or an inorganic film which can be formed by a low temperature process. When the organic film is used for the touch insulating film 152, after coating the organic film over the substrate 111, the organic film is cured at a temperature of 100° C. or lower to form the touch insulating film 152 to suppress the damage of the organic layer 124 vulnerable to the high temperature. When the inorganic film is used for the touch insulating film 152, in order to suppress the damage of the organic layer 124 vulnerable to the high temperature, a low temperature chemical vapor deposition (CVD) process and a washing process are repeated at least twice to form the touch insulating film 152 with a multi-layered structure.

A partial area of the touch insulating film 152 is selectively removed to form a touch contact hole to expose a part of the bridge pattern 155.

A touch electrode (or a touch line) 156 can be disposed on the touch insulating film 152. However, it is not limited thereto and the bridge pattern can be disposed on the touch insulating film 152.

For example, the touch electrode 156 can be electrically connected to the bridge pattern 155 through the touch contact hole.

Further, the touch planarization layer 157 can be disposed on the touch electrode 156, but is not limited thereto and the touch planarization layer can be omitted.

A black matrix 175 can be disposed on the touch planarization layer 157.

The black matrix 175 can be located over the touch electrode 156.

The black matrix 175 can be located so as to correspond to the first non-emission area NEA1.

A color filter layer 170 can be disposed in the main emission area EA1, the first reflective emission area EA2, the second reflective emission area EA3, the second non-emission area NEA2, and the third non-emission area NEA3 between the back matrixes 175.

For example, the color filter layer 170 can include a red color filter layer, a green color filter layer, and a blue color filter layer, but is not limited thereto and further include a white color filter layer.

The black matrix 175 can be disposed on the boundary of color filter layers 170 with different colors. Therefore, the black matrix 175 can define a sub pixel area. Sub pixel areas defined by the black matrix 175 can be a red sub pixel area, a green sub pixel area, and a blue sub pixel area. Further, the sub pixel area can further include a white sub pixel area. For example, an area in which the red color filter layer is disposed can correspond to a red sub pixel area, an area in which the green color filter layer is disposed can correspond to a green sub pixel area, and an area in which a blue color filter layer is disposed can correspond to a blue sub pixel area. Further, an area in which a white color filter layer is disposed can correspond to a white sub pixel area.

For example, in the area in which the red color filter layer is disposed, red light can be emitted, in the area in which the green color filter layer is disposed, green light can be emitted, in the area in which the blue color filter layer is disposed, blue light can be emitted, and in the area in which the white color filter layer is disposed, white light can be emitted

Hereinafter, a manufacturing method of the display panel according to the first embodiment of the present disclosure configured as described above will now be described in detail with reference to the drawings.

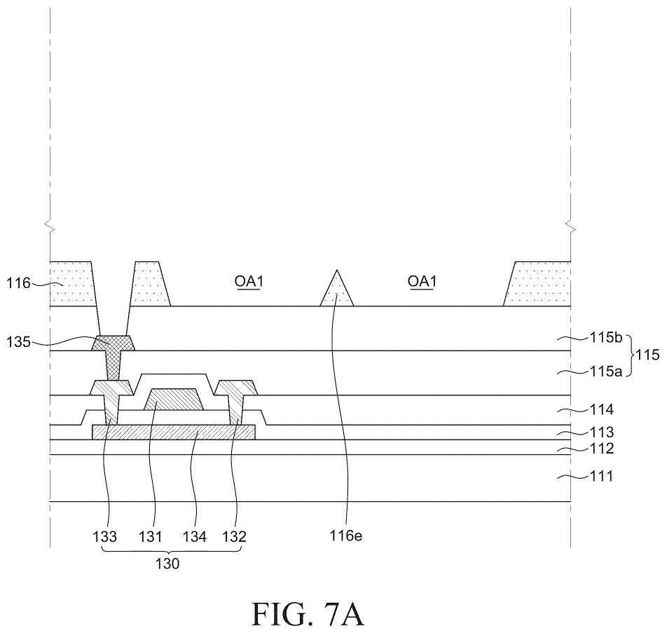

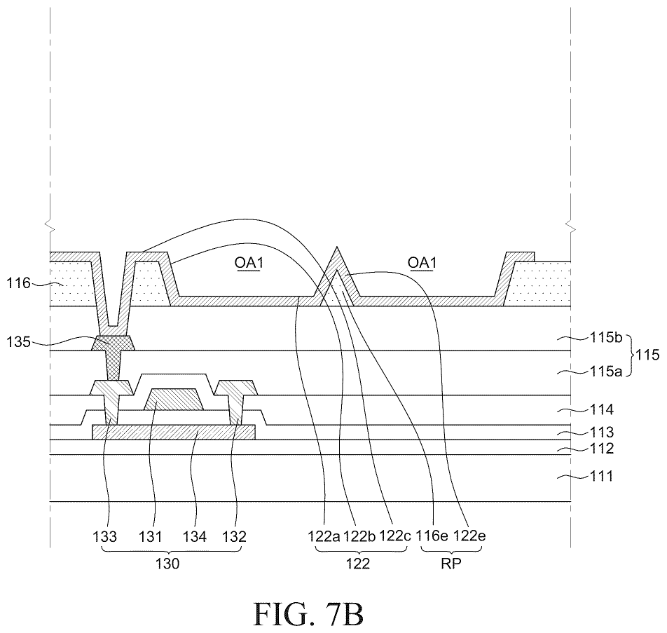

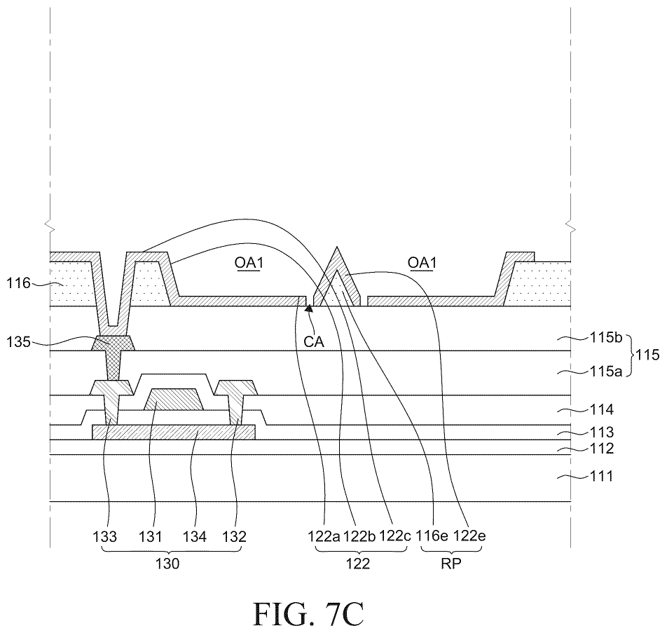

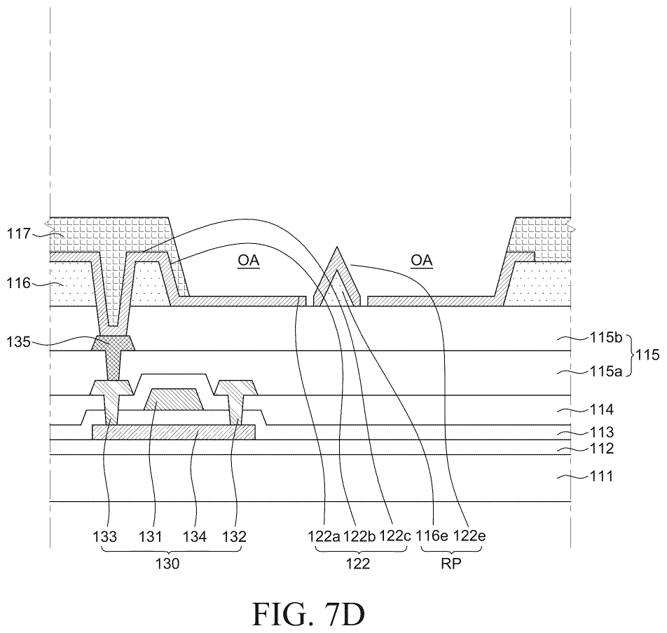

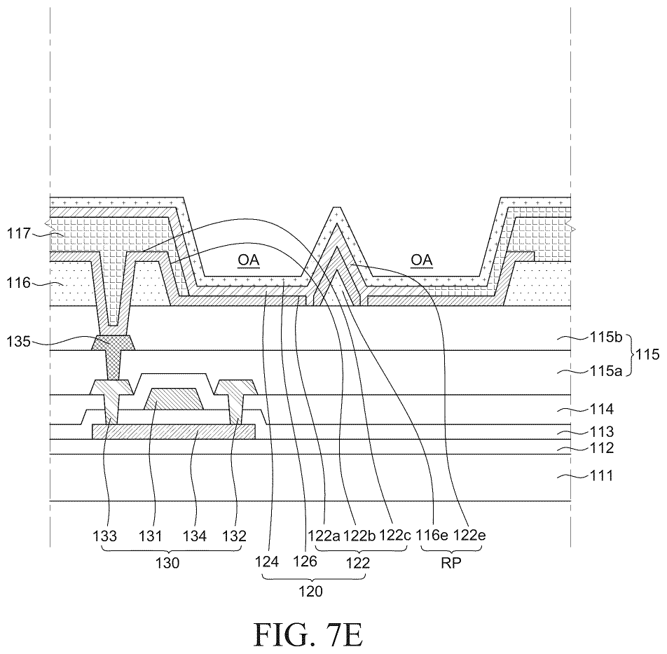

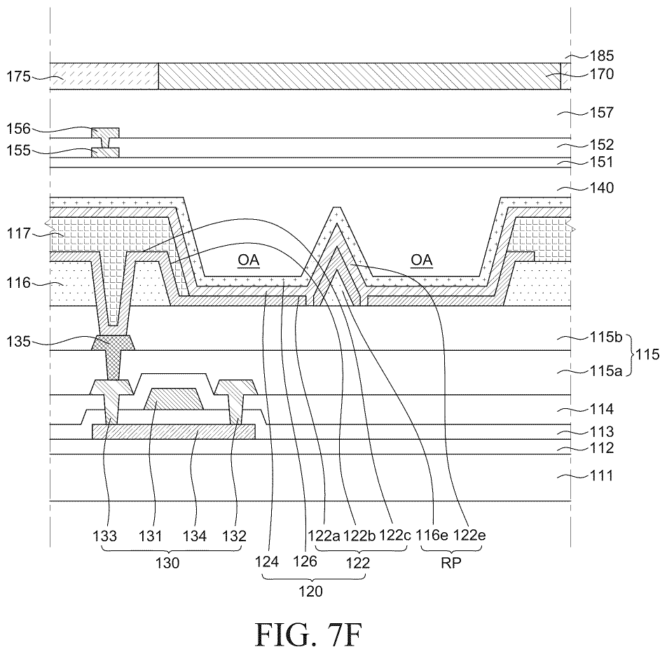

FIGS. 7A to 7F are views sequentially illustrating manufacturing processes of the display panel according to the first embodiment of the present disclosure of FIG. 4.

Hereinafter, the same configuration is denoted by the same reference numeral and the description of the same reference numeral can refer to FIGS. 1 to 5B.

First, referring to FIG. 7A, a buffer layer 112, such as a multi-buffer layer or a lower buffer layer, can be formed over the substrate 111.

The semiconductor layer 134 can be formed in the active area on the buffer layer 112.

The gate insulating film 113 can be formed on the semiconductor layer 134.

A gate line is formed in a first direction and a gate electrode 131 which is connected to the gate line can be formed, on the gate insulating film 113.

An interlayer insulating film 114 can be formed on the gate electrode 131 so as to cover the gate electrode 131.

At this time, a partial area of the interlayer insulating film 114 and the gate insulating film 133 is selectively removed to form a plurality of contact holes which exposes both ends of the semiconductor layer 134.

The data line can be formed on the interlayer insulating film 114 in a second direction intersecting the gate line.

Further, a source electrode 132 and a drain electrode 133 which are connected to both ends of the semiconductor layer 134, respectively, can be formed on the interlayer insulating film 114.

The planarization layer 115 can be formed on the data line and the source electrode 132 and the drain electrode 133.

The first bank 116 can be formed on the planarization layer 115.

For example, the first bank 116 can be formed in a first non-emission area NEA1 and a first reflective emission area EA2 of the substrate 111 on the second planarization layer 115b.

A part of the first bank 116 which substantially corresponds to the main emission area EA1, the second non-emission area NEA2, and the third non-emission area NEA3 can be open. For example, the first bank 116 can include a first open area OA1 which is formed by removing (opening) a part which substantially corresponds to the main emission area EA1, the second non-emission area NEA2, and the third non-emission area NEA3.

The first open area OA1 can have a larger size than an open area OA to be described below.

In the meantime, the base layer 116e with an inclined side surface can be formed over the second planarization layer 115b in which the first bank 116 is not disposed.

The base layer 116e can be formed to have an inclined side surface and a triangular cross-section overall, but is not limited thereto.

For example, the base layer 116e can be formed by the same organic material as the first bank 116, but is not limited thereto. The base layer 116e can be configured by the same process as the first bank 116, but is not limited thereto.

Further, for example, in the plan view, the base layer 116e can have a cross-shape which divides the main emission area EA1 into four, but the present disclosure is not limited thereto and can have a lattice shape which divides the main emission area EA1 into four or more.

Next, referring to FIG. 7B, the anode 122 can be formed on the second planarization layer 115b and the first bank 116.

Further, the reflective layer 122e can be formed on the base layer 116e.

The anode 122 can include a first area 122a which is disposed on the second planarization layer 115b to be in contact with the second planarization layer 115b and a second area 122b which extends from the first area 122a to be disposed on the side surface of the first bank 116. The first area 112a has a surface substantially parallel to a surface of the substrate 111 and the second area 122b has a surface which has a predetermined angle with respect to the substrate 111.

Further, for example, the anode 122 can include a third area 122c which extends from the second area 122b in one direction to be electrically connected to the connection electrode 135 through a contact hole.

For example, the reflective layer 122e can be formed by the same conductive material as the anode 122, but is not limited thereto. The reflective layer 122e can be formed by the same photo process as the anode 122, but is not limited thereto. Further, the reflective layer 122e can be formed to cover a side surface of the base layer 116e. Further, the reflective layer 122e can be formed to cover the entire base layer 116e.

The anode 122 and the reflective layer 122e can include reflective films formed of a reflective metal.

For example, the second area 122b of the anode 122 disposed on the side surface of the first bank 116 and the reflective layer 122e disposed on the side surface of the base layer 116e can be formed to have a taper at an angle of approximately 30° to 60°, but are not limited thereto.

Next, referring to FIG. 7C, the first area 122a of the anode 122 around the reflective layer 122e is cut (or removed) using the laser cutting to form the cutting area CA.

The cutting area CA is formed by cutting (or removing) the first area 122a of the anode 122 around the reflective layer 122e to expose the second planarization layer 115b therebelow. Accordingly, the reflective layer 122e can be separated from the first area 122a of the anode 122. The reflective layer 122e can be electrically isolated.

Here, the base layer 116e and the reflective layer 122e can configure the reflection pattern RP.

The reflection pattern RP can have an inclined side surface and a triangular cross-section overall, but is not limited thereto.

Further, for example, in the plan view, the reflection pattern RP can have a cross-shape which divides the main emission area EA1 into four, but the present disclosure is not limited thereto and can have a lattice shape which divides the main emission area EA1 into four or more.

Further, the reflection pattern RP can be spaced apart from the first area 122a of the anode 122 by a predetermined distance.

Next, referring to FIG. 7D, the second bank 117 can be formed over the first bank 116 and the anode 122 while covering a part of the anode 122.

For example, the second bank 117 can cover a part of the first area 122a and the second area 122b and the third area 122c of the anode 122. The second bank 117 can cover a part of an edge of the first area 122a. Further, the second bank 117 can cover the entire second area 122b and the entire third area 122c.

A part of the second bank 117 corresponding to the main emission area EA1 can be open. For example, the second bank 117 can include an open area OA obtained by removing (opening) a part corresponding to the main emission area EA1 of a sub pixel SP.

According to the first embodiment of the present disclosure, the second bank 117 is not formed over the reflection pattern RP.

Next, referring to FIG. 7E, the organic layer 124 can be disposed on the top surface and a side portion of the second bank 117, including the open area OA of the second bank 117.

Further, the organic layer 124 can be disposed and extend over the top surface and the side portion of the reflection pattern RP, including the cutting area CA.

Further, the cathode 126 can be formed on the organic layer 124 so as to be opposite to the anode 122 with the organic layer 124 therebetween.

Next, referring to FIG. 7F, an encapsulation unit 140 can be formed over the cathode 126 to protect the light emitting diode 120.

A touch panel configured by a touch buffer film 151, a bridge pattern 155, a touch insulating film 152, a touch electrode (or a touch line) 156, and a touch planarization layer 157 can be disposed over the encapsulation unit 140.

The black matrix 175 and the color filter layer 170 can be formed on the touch planarization layer 157.

In the meantime, according to the present disclosure, in order to suppress the short-circuit caused by metal burrs generated during the laser cutting, the reflection pattern can be formed on the top surface of the planarization layer in which a part of the thickness is removed (etched), which will now be described in detail with reference to the drawings.

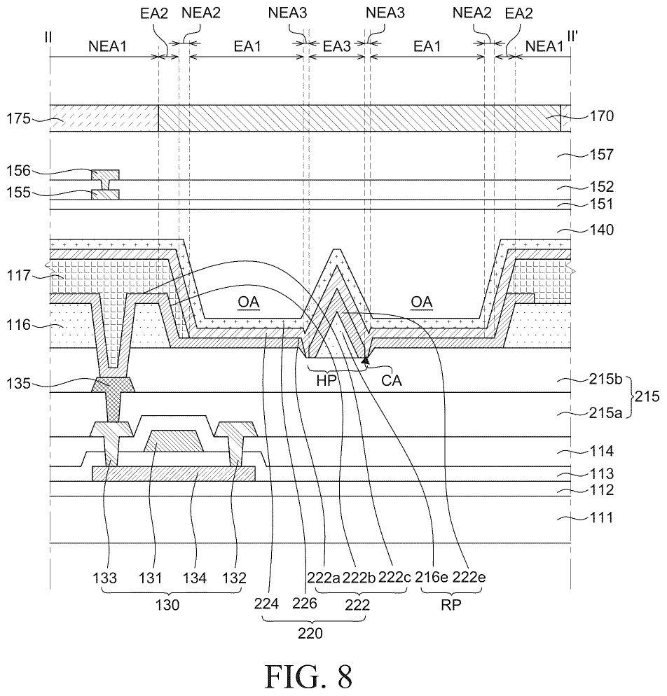

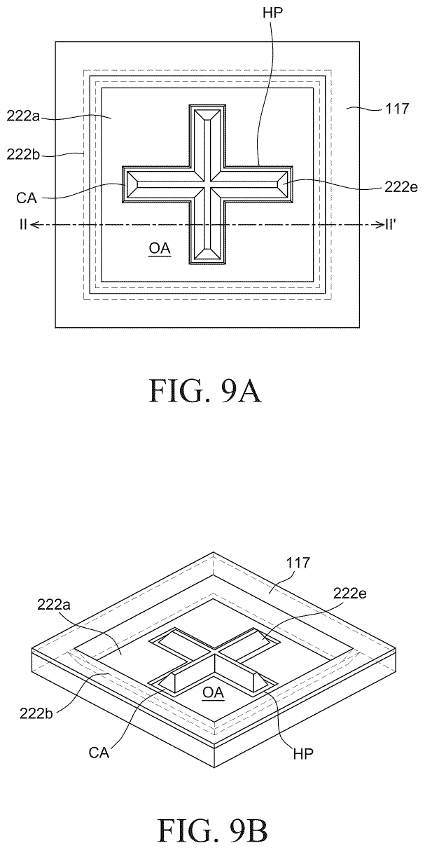

FIG. 8 is a view illustrating a part of a cross-section of a display panel according to a second embodiment of the present disclosure. FIGS. 9A and 9B are a plan view and a perspective view illustrating a part of a sub pixel of the display panel according to the second embodiment of the present disclosure.

The second embodiment of FIGS. 8, 9A, and 9B is substantially the same as the first embodiment of FIGS. 4, 5A, and 5B described above except that a reflection pattern RP is disposed on a top surface of a second planarization layer 215b in which a part of the thickness is removed (etched). Therefore, a redundant description will be omitted or may be briefly provided. The same configuration will be denoted with the same reference numeral. Hereinafter, the description for the same reference numeral can be understood by referring to FIGS. 1 to 5B.

Particularly, FIG. 8 illustrates a part of a cross-sectional structure of one sub pixel SP taken along the line II-II′ of FIG. 9A.

FIG. 9A is a plan view illustrating an example that a second bank 117 is disposed over the anode 222 of FIG. 8 and FIG. 9B is a perspective view of FIG. 9A. Here, in FIGS. 9A and 9B, for the convenience of description, configurations over the anode 222 and the second bank 117 are omitted.

Referring to FIGS. 8, 9A, and 9B, a planarization layer 215 can be disposed over the substrate 111.

The planarization layer 215 can include a first planarization layer 215a and a second planarization layer 215b.

According to the second embodiment of the present disclosure, a groove pattern HP is formed by removing (etching) a part of an upper thickness of a partial area of the second planarization layer 215b. For example, the groove pattern HP can be formed by removing (etching) a part of the upper thickness of the second planarization layer 215b in which the reflection pattern RP is to be disposed. The groove pattern HP can have a predetermined depth by considering a height of the reflection pattern RP to be formed. When the reflection pattern RP has a cross shape which divides the main emission area EA1 into four, the groove pattern HP can also have a cross shape which divides the main emission area EA1 into four. In the plan view, the groove pattern HP can have a larger area than the reflection pattern RP to place the reflection pattern RP in the groove pattern HP.

The groove pattern HP can be formed by the photo process.

The first bank 116 can be disposed on the second planarization layer 215b in which the groove pattern HP is formed.

According to the second embodiment of the present disclosure, a reflection pattern RP having an inclined side surface is disposed in the groove pattern HP of the second planarization layer 215b.

The reflection pattern RP can have an inclined side surface and a triangular cross-section overall, but is not limited thereto.

Further, for example, in the plan view, the reflection pattern RP can have a cross-shape which divides the main emission area EA1 into four, but the present disclosure is not limited thereto and can have a lattice shape which divides the main emission area EA1 into four or more.

Further, the reflection pattern RP can be spaced apart from the first area 222a of the anode 222 by a predetermined distance.

The anode 222 can include a first area 222a which is disposed on the second planarization layer 215b to be in contact with the second planarization layer 215b and a second area 222b which extends from the first area 222a to be disposed on the side surface of the first bank 116. The first area 222a has a surface substantially parallel to a surface of the substrate 111 and the second area 222b has a surface which has a predetermined angle with respect to the substrate 111. Further, for example, the anode 222 can include a third area 222c which extends from the second area 222b in one direction to be electrically connected to the connection electrode 135 through a contact hole.

For example, the reflection pattern RP can be configured by a base layer 216e formed of an organic material and a reflective layer 222e formed of a reflective material, but is not limited thereto.

Further, according to the second embodiment of the present disclosure, a cut (ruptured) area CA in which the first area 222a of the anode 222 is cut (or removed) is provided around the reflection pattern RP. The cutting area CA can be located in the groove pattern HP around the reflection pattern RP.

The cutting area CA is formed by cutting (or removing) the first area 222a of the anode 222 around the reflection pattern RP to expose the second planarization layer 215b therebelow. Accordingly, the reflective layer 222e of the reflection pattern RP can be separated from the first area 222a of the anode 222. For example, the reflection pattern RP can be electrically isolated.

The cutting area CA can be formed using the laser.

According to the second embodiment, the reflection pattern RP is formed in the groove pattern HP of the second planarization layer 215b in which a part of the thickness is removed (etched) so that the short-circuit caused by the metal burrs generated during the laser cutting can be suppressed. For example, when the cutting area CA is formed using the laser, a metal burr in which an end of the first area 222a of the anode 222 which is melted by the laser is rolled up is generated. According to the second embodiment of the present disclosure, the cutting area CA is formed in the groove pattern HP of the second planarization layer 215b so that the metal bur is not generated due to the step. Therefore, the reflection pattern RP can be surely electrically isolated from the anode 222 so that the light extraction efficiency can be improved.

The light emitting diode 220 configured by the anode 222, the organic layer 224, and the cathode 226 can be disposed over the second planarization layer 215b.

The light emitting diode 220 and configurations thereabove are substantially the same as the first embodiment described above so that a redundant description will be omitted.

In the meantime, according to the present disclosure, each of the main emission area, the first reflective emission area and the second reflective emission area has a shape other than the rectangular shape and the cross shape, which will now be described in detail with reference to the drawings.

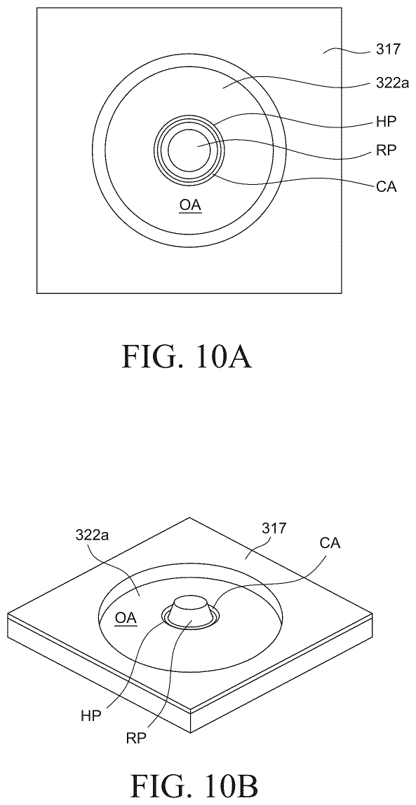

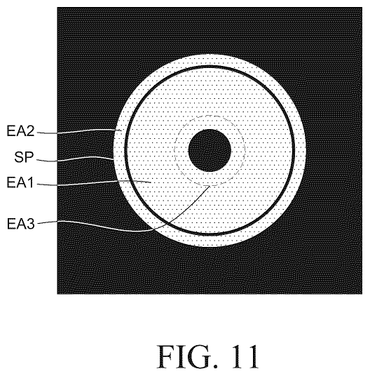

FIGS. 10A and 10B are respectively a plan view and a perspective view illustrating a part of a sub pixel according to a third embodiment of the present disclosure. FIG. 11 is a view illustrating an emission image according to the third embodiment of the present disclosure.

The third embodiment of FIGS. 10A, 10B, and 11 is substantially the same as the second embodiment of FIGS. 8, 9A, and 9B described above except for shapes of an anode 322, a reflection pattern RP, and emission areas EA1, EA2, and EA3 thereby so that a redundant description will be omitted or may be briefly provided. The same configuration will be denoted with the same reference numeral. Hereinafter, the description for the same reference numeral can be understood by referring to FIGS. 1 to 9B.

Here, FIG. 10A is a plan view illustrating an example that a second bank 317 is disposed over the anode 322 and FIG. 10B is a perspective view of FIG. 10A according to the third embodiment of the present disclosure. Further, in FIGS. 10A and 10B, for the convenience of description, configurations over the anode 322 and the second bank 317 are omitted.

FIG. 11 illustrates an emission image of the third embodiment in which a second bank 317 is not formed over the reflection pattern RP and the cutting area CA is formed around the reflection pattern RP.

Referring to FIGS. 10A, 10B, and 11, the display panel of the third embodiment of the present disclosure can include a plurality of pixels configured by a first sub pixel, a second sub pixel, and a third sub pixel.

For example, the sub pixel SP can have an approximately circular shape, but is not limited thereto. At this time, a shape of the sub pixel SP can be defined by a shape of a first area 322a of the anode 322, but it is not limited thereto. Further, the sub pixel SP can have an oval shape or a polygonal shape. Further, the sub pixel SP can have a mixed shape of a circular shape, an oval shape or a polygonal shape.

In the meantime, in the third embodiment of the present disclosure, the anode 322 has a side mirror (SM) structure so that a first reflective emission area EA2 is added in addition to the main emission area EA1 so that each emission area can expand as compared with each sub pixel SP.

Further, in the third embodiment of the present disclosure, a reflection pattern RP is installed in the main emission area EA1 and a cut (ruptured) area CA in which the first area 322a of the anode 322 is cut is formed around the reflection pattern RP by means of the laser to add the second reflective emission area EA3. Specifically, a second bank 317 is not formed over the reflection pattern RP to further improve the light extraction efficiency in accordance with the reduction in the non-emission area.

Further, according to the third embodiment of the present disclosure, in the plan view, the reflection pattern RP has a circular shape in response to the shape of the sub pixel SP.

For example, the main emission area EA1 can have a circular shape in response to the shape of the sub pixel SP and the first reflective emission area EA2 can have a circular frame shape. Further, the second reflective emission area EA3 can have a circular shape or a circular frame shape, in response to the shape of the reflection pattern RP.

In the meantime, the reflection pattern of the present disclosure can have a lattice shape which divides the main emission area into four or more, which will be described in detail.

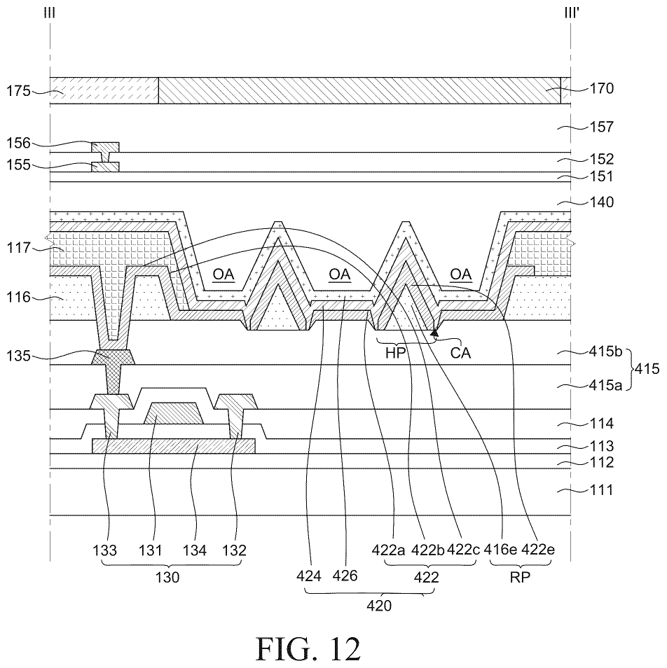

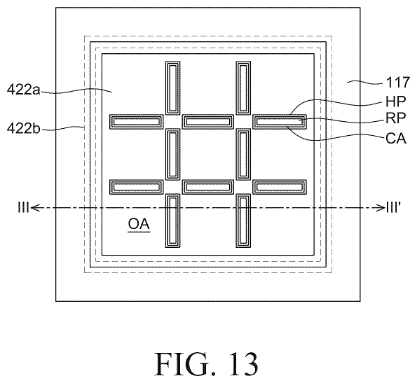

FIG. 12 is a view illustrating a part of a cross-section of a display panel according to a fourth embodiment of the present disclosure. FIG. 13 is a plan view illustrating a part of a sub pixel of the display panel according to the fourth embodiment of the present disclosure.

The fourth embodiment of FIGS. 12 and 13 is substantially the same as the second embodiment of FIGS. 8, 9A, and 9B except that the reflection pattern RP has a lattice shape which divides the main emission area EA1 into four or more, so that a redundant description will be omitted or may be briefly provided. The same configuration will be denoted with the same reference numeral. Hereinafter, the description for the same reference numeral can refer to FIGS. 1 to 9B.

At this time, FIG. 12 illustrates a part of a cross-sectional structure of one sub pixel SP taken along the line III-III′ of FIG. 13. FIG. 13 is a plan view illustrating an example in which the second bank 117 is disposed over the anode 422 of FIG. 12 according to the fourth embodiment of the present disclosure. For the convenience of description, in FIG. 13, configurations over the anode 422 and the second bank 117 are omitted.

Referring to FIGS. 12 and 13, a planarization layer 415 can be disposed over the substrate 111.

The planarization layer 415 can include a first planarization layer 415a and a second planarization layer 415b.

According to the fourth embodiment of the present disclosure, like the second and third embodiments, a groove pattern HP is formed by removing (etching) a part of an upper thickness of a partial area of the second planarization layer 415b. For example, the groove pattern HP can be formed by removing (etching) a part of the upper thickness of the second planarization layer 415b in which the reflection pattern RP is to be disposed. The groove pattern HP can have a predetermined depth by considering a height of the reflection pattern RP to be formed.

Further, according to the fourth embodiment of the present disclosure, when the reflection pattern RP has a lattice shape which divides the main emission area EA1 into four or more, the groove pattern HP can also have a lattice shape which divides the main emission area EA1 into four or more. In the plan view, the groove pattern HP can have a larger area than the reflection pattern RP to place the reflection pattern RP in the groove pattern HP.

For example, in the plan view, the reflection pattern RP can be a lattice shape, but can be separated to four rectangular shapes up, down, left, and right, but it not limited thereto. Therefore, the groove pattern HP also has a lattice shape overall, but can be separated to four rectangular shapes up, down, left, and right.

The groove pattern HP can be formed by the photo process.

The first bank 116 can be disposed on the second planarization layer 415b in which the groove pattern HP is formed.

According to the fourth embodiment of the present disclosure, a reflection pattern RP having an inclined side surface is disposed in the groove pattern HP of the second planarization layer 415b.

The reflection pattern RP can have an inclined side surface and a triangular cross-section overall, but is not limited thereto.

Further, the reflection pattern RP can be spaced apart from the first area 422a of the anode 422 by a predetermined distance.

The anode 422 can include a first area 422a which is disposed on the second planarization layer 415b to be in contact with the second planarization layer 415b and a second area 422b which extends from the first area 422a to be disposed on the side surface of the first bank 116. The first area 422a has a surface substantially parallel to a surface of the substrate 111 and the second area 422b has a surface which has a predetermined angle with respect to the substrate 111. Further, for example, the anode 422 can include a third area 422c which extends from the second area 422b in one direction to be electrically connected to the connection electrode 135 through a contact hole.

For example, the reflection pattern RP can be configured by a base layer 416e formed of an organic material and a reflective layer 422e formed of a reflective material, but is not limited thereto.

Further, according to the fourth embodiment of the present disclosure, a cut (ruptured) area CA in which the first area 422a of the anode 422 is cut (or removed) is provided around the reflection pattern RP. The cutting area CA can be located in the groove pattern HP around the reflection pattern RP.

The cutting area CA is formed by cutting (or removing) the first area 422a of the anode 422 around the reflection pattern RP to expose the second planarization layer 415b therebelow. Accordingly, the reflective layer 422e of the reflection pattern RP can be separated from the first area 422a of the anode 422. For example, the reflection pattern RP can be electrically isolated.

The cutting area CA can be formed using the laser.

The light emitting diode 420 configured by the anode 422, the organic layer 424, and the cathode 426 can be disposed over the second planarization layer 415b.

The light emitting diode 420 and configurations thereabove are substantially the same as the first, second, and third embodiments described above so that a redundant description will be omitted.

The embodiments of the present disclosure can also be described as follows:

According to an aspect of the present disclosure, there is provided a display device. The display device includes a planarization layer disposed over a substrate, a first bank and a base layer disposed on the planarization layer, an anode which is disposed on the planarization layer, including a side surface of the first bank, a reflective layer disposed so as to cover the base layer, a second bank covering a part of the anode and the first bank and disposed over the anode and the first bank, an organic layer disposed over the substrate on which the second bank is disposed and a cathode disposed on the organic layer.

The display device can further comprise an encapsulation unit disposed over the cathode and a black matrix and a color filter layer disposed over the encapsulation unit.

The anode can include a first area which is disposed on the planarization layer to be in contact with the planarization layer, a second area which extends from the first area to be disposed on a side surface of the first bank and has a surface having a predetermined angle with respect to the substrate and a third area which extends from the second area in the other direction to be electrically connected to a thin film transistor through a contact hole.

The second bank can cover a part of an edge of the first area, the entire second area and the entire third area.

The base layer can be configured by the same organic material as the first bank.

The base layer can have an inclined side surface and a triangular cross-section.

The reflective layer can be configured by the same conductive material as the anode.

In a plan view, the base layer and the reflective layer can have a cross-shape or a lattice shape.

The reflective layer can be separated from the first area to be electrically isolated.

The base layer and the reflective layer can configure a reflection pattern.

A groove pattern can be configured by removing a part of an upper thickness in a partial area of the planarization layer and the reflection pattern can be disposed in the groove pattern.

The reflection pattern can have an inclined side surface and a triangular cross-section overall.

In a plan view, the reflection pattern can have a cross-shape or a lattice shape.

The reflection pattern can be disposed to be spaced apart from the first area with a predetermined distance.

A cutting area can be provided around the reflection pattern where the first area is cut and the cutting area can have a cross or lattice shape in accordance with a shape of the reflection pattern.

The cutting area can expose the planarization layer.

The organic layer can be disposed and extends over a top surface and a side portion of the reflection pattern, including the cutting area.

The second bank can be not disposed over the reflection pattern.

The second bank can include an open area configured by removing a part corresponding to a main emission area of each sub pixel, a first reflective emission area can be configured around the main emission area so as to correspond to the second area, and a second reflective emission area can be configured between the main emission areas so as to correspond to the reflective layer.

In a plan view, the main emission area can have a rectangular shape, the first reflective emission area can have a rectangular frame shape, and the second reflective emission area can have a cross-shape or the main emission area can have a circular shape, an oval shape, or a polygonal shape, the first reflective emission area can have a circular, oval, or polygonal frame shape, and the second reflective emission area can have the circular shape, the oval shape, or a lattice shape.

Although the embodiments of the present disclosure have been described in detail with reference to the accompanying drawings, the present disclosure is not limited thereto and can be embodied in many different forms without departing from the technical concept of the present disclosure. Therefore, the embodiments of the present disclosure are provided for illustrative purposes only but not intended to limit the technical concept of the present disclosure. The scope of the technical concept of the present disclosure is not limited thereto.

Therefore, it should be understood that the above-described embodiments are illustrative in all aspects and do not limit the present disclosure. All the technical concepts in the equivalent scope of the present disclosure should be construed as falling within the scope of the present disclosure.

What is claimed is:

1. A display device, comprising:
a planarization layer disposed over a substrate;
a first bank and a base layer disposed over the planarization layer;
an anode disposed over the planarization layer and a side surface of the first bank;
a reflective layer disposed to cover the base layer;
a second bank covering a part of the anode and the first bank and disposed over the anode and the first bank;
an organic layer disposed over the substrate on which the second bank is disposed; and
a cathode disposed over the organic layer.

2. The display device according to claim 1, further comprising:
an encapsulation unit disposed over the cathode; and
a black matrix and a color filter layer disposed over the encapsulation unit.

3. The display device according to claim 1, wherein the anode includes:
a first area disposed over the planarization layer to be in contact with the planarization layer;
a second area extending from the first area to be disposed over a side surface of the first bank, and including a surface having a predetermined angle with respect to the substrate; and
a third area extending from the second area in another direction to be electrically connected to a thin film transistor through a contact hole.

4. The display device according to claim 3, wherein the second bank covers a part of an edge of the first area, the entire second area and the entire third area.

5. The display device according to claim 1, wherein the base layer includes a same organic material as the first bank.

6. The display device according to claim 1, wherein the base layer has an inclined side surface and a triangular cross-section.

7. The display device according to claim 1, wherein the reflective layer includes a same conductive material as the anode.

8. The display device according to claim 1, wherein in a plan view, the base layer and the reflective layer have a cross-shape or a lattice shape.

9. The display device according to claim 3, wherein the reflective layer is separated from the first area to be electrically isolated.

10. The display device according to claim 3, wherein the base layer and the reflective layer form a reflection pattern.

11. The display device according to claim 10, wherein a groove pattern is configured by removing a part of an upper thickness in a partial area of the planarization layer and
wherein the reflection pattern is disposed in the groove pattern.

12. The display device according to claim 10, wherein the reflection pattern has an inclined side surface and a triangular cross-section overall.

13. The display device according to claim 10, wherein in a plan view, the reflection pattern has a cross-shape or a lattice shape.

14. The display device according to claim 10, wherein the reflection pattern is disposed to be spaced apart from the first area with a predetermined distance.

15. The display device according to claim 10, wherein a cutting area is provided around the reflection pattern where the first area is cut, and the cutting area has a cross or lattice shape in accordance with a shape of the reflection pattern.

16. The display device according to claim 15, wherein the cutting area exposes the planarization layer.

17. The display device according to claim 15, wherein the organic layer is disposed and extends over a top surface and a side portion of the reflection pattern including the cutting area.

18. The display device according to claim 10, wherein the second bank is not disposed over the reflection pattern.

19. The display device according to claim 3, wherein the second bank includes an open area configured by removing a part corresponding to a main emission area of each sub pixel among a plurality of sub pixels,
wherein a first reflective emission area is configured around the main emission area so as to correspond to the second area, and
wherein a second reflective emission area is configured between the main emission areas so as to correspond to the reflective layer.

20. The display device according to claim 19, wherein in a plan view,
the main emission area has a rectangular shape, the first reflective emission area has a rectangular frame shape, and the second reflective emission area has a cross-shape, or
the main emission area has a circular shape, an oval shape, or a polygonal shape, the first reflective emission area has a circular, oval, or polygonal frame shape, and the second reflective emission area has a circular shape, an oval shape, or a lattice shape.
